(19) United States
(12) Patent Application Publication
(10) Pub. No.: US 2024/0057465 A1
(43) Pub. Date: Feb. 15, 2024

(54) QUANTUM DOT COLOR FILTER SUBSTRATE, MANUFACTURING METHOD THEREOF, AND QUANTUM DOT DISPLAY DEVICE

(71) Applicant: Shenzhen China Star Optoelectronics Semiconductor Display Technology Co., Ltd., Shenzhen (CN)

(72) Inventor: Wenxiang PENG, Shenzhen (CN)

(21) Appl. No.: 17/603,063

(22) PCT Filed: Sep. 14, 2021
(86) PCT No.: PCT/CN2021/118083

§ 371 Date: Mar. 2, 2023

(30) Foreign Application Priority Data
Aug. 27, 2021 (CN) 202110995186.9

(51) Int. Cl. H10K 71/00; H10K 59/38; H10K 59/80

(52) U.S. Cl. CPC H10K 71/821; H10K 59/38; H10K 59/877; H10K 59/8792; H10K 2102/331

(57) ABSTRACT

A quantum dot color filter substrate, a manufacturing method thereof, and a quantum dot display device are provided. The quantum dot color filter substrate includes a substrate, a color filter layer, a barrier layer, a quantum dot light-emitting layer, a scattering layer, and an encapsulation layer. The quantum dot light-emitting layer includes a plurality of quantum dot light-emitting units and a second black photoresist layer, wherein, the side surfaces of the second black photoresist layer adjoining the plurality of quantum dot light-emitting units are inclined surfaces or concave curved surfaces.

### FIELD OF INVENTION

The present invention relates to a field of display technology and particularly relates to a quantum dot color filter substrate and a manufacturing method thereof, and a quantum dot display device.

### BACKGROUND OF INVENTION

Quantum dots (QDs) are a kind of nanocrystalline semiconductor material, usually in a colloidal state. The particle sizes of the quantum dots are generally between 1 and 20 nm. Common quantum dots are composed of IV, II-VI, IV-VI, or III-V elements, such as silicon quantum dots, germanium quantum dots, cadmium sulfide quantum dots, and cadmium selenide quantum dots. Due to quantum confinement effect and surface effect, quantum dots have excellent luminescence characteristics such as wide and continuous excitation spectrum, narrow and symmetrical emission spectrum, luminous color adjustable with sizes of quantum dots, and high photochemical stability. Therefore, a better color rendering index is achieved. Quantum dots are mainly used in fields of electronics, optoelectronics, optics, and life sciences.

The quantum dot color filter substrate can be excited by a blue backlight, such as a blue organic light-emitting diode (OLED), a blue micro-light-emitting diode (micro-LED), or a blue sub-millimeter light-emitting diode (mini-LED) to excite color resistances composed of quantum dots to emit light. Such a quantum dot display device including a quantum dot color filter substrate and a light-emitting diode device not only has characteristics of autonomous light emission, thinness, and flexibility of the light-emitting diode device but also has advantages of a high color gamut of quantum dots. The quantum dot display device uses photoluminescence characteristics of the quantum dots in the quantum dot color filter substrate to convert blue light emitted by the backlight into red light and green light, thereby achieving the purpose of a full-color display.

### Technical Problem

The quantum dot color filter substrate is mainly composed of a color filter and a quantum dot film layer, where the quantum dot film layer can be formed by inkjet printing (IJP). The technical advantage of IJP lies in an ability to control a position and a volume of ink dripped, so as to realize printing and film formation in an area of a pixel size level. However, quantum dot material in the quantum dot color filter substrate is printed inside banks of the black photoresist layer in the substrate, and the black photoresist layer is a black material so that when the quantum dot material is excited to emit light, part of the light will be absorbed by the black material, which leads to a problem of weak light emission from a quantum dot color filter layer.

As mentioned above, in current quantum dot color filter technology, when the quantum dot material is excited and emits light, part of the light will be absorbed by a black photoresist layer material, resulting in a problem of low light output efficiency of the quantum dot color filter layer. This problem needs to be solved.

### SUMMARY OF INVENTION

In order to solve the above technical problem, the present invention utilizes a natural phenomenon, i.e., when a droplet with solute particles drops on a surface of an object, under a mutual competition of several forces, a liquid flow from center to edge is formed. This causes the natural phenomenon in which the liquid flow can bring almost all the solute particles to the edge. This natural phenomenon is named coffee-ring effect and was first published in Nature in 1997 by a research team at the University of Chicago.

The specific method of the present invention is to print the scattering ink on the surface of the barrier layer in advance and utilize the coffee ring effect of the scattering ink on the surface of the barrier layer and the characteristic that the scattering ink has a stronger affinity with the material of the second black photoresist layer, to cause the solute particles (scattering particles) in the scattering ink gather at the edge of the position between the barrier layer and the bottom of the second black photoresist layer and climb along an inclined or concave curved surface, thereby forming a scattering film layer on the side surface of the second black photoresist layer. With this method, a scattering layer can be formed on the edge of the second black photoresist layer. When the quantum dot material of the quantum dot color filter layer is excited to emit light, the reflection effect of the scattering layer is utilized to reflect part of the light that should be absorbed by the second black photoresist layer material to achieve the purpose of improving the luminous efficiency of the quantum dot color filter substrate.

The present invention provides a quantum dot color filter substrate, including: a substrate; a color filter layer disposed on the substrate, wherein the color filter layer includes a plurality of color photoresist units and a first black photoresist layer; a barrier layer disposed on the color filter layer; a quantum dot light-emitting layer disposed on the barrier layer, wherein the quantum dot light-emitting layer includes a plurality of quantum dot light-emitting units and a second black photoresist layer, and the plurality of quantum dot light-emitting units are separated by the second black photoresist layer; a scattering layer disposed on side surfaces of the second black photoresist layer adjoining the plurality of quantum dot light-emitting units; and an encapsulation layer disposed on the quantum dot light-emitting layer.

In the quantum dot color filter substrate according to an embodiment of the present invention, the side surfaces of the second black photoresist layer adjoining the plurality of quantum dot light-emitting units are inclined surfaces.

In the quantum dot color filter substrate according to an embodiment of the present invention, each inclined surface is inclined toward a direction away from one of the plurality of quantum dot light-emitting units adjoining thereto.

In the quantum dot color filter substrate according to an embodiment of the present invention, the side surfaces of the second black photoresist layer adjoining the plurality of quantum dot light-emitting units are concave curved surfaces.

In the quantum dot color filter substrate according to an embodiment of the present invention, a material of the scattering layer includes a matrix and scattering particles dispersed in the matrix.

In the quantum dot color filter substrate according to an embodiment of the present invention, the matrix includes a thermosetting resin selected from titanium dioxide, silicon dioxide, organic silicon compounds, polystyrene, or a combination thereof.

The present invention provides a quantum dot display device, including: a quantum dot color filter substrate; and a backlight substrate arranged opposite to the quantum dot color filter substrate; wherein the backlight substrate is selected from any of a blue organic light-emitting diode substrate, a blue micro light-emitting diode substrate, or a blue submillimeter light-emitting diode substrate. The quantum dot color filter substrate includes: a substrate; a color filter layer disposed on the substrate, wherein the color filter layer comprises a plurality of color photoresist units and a first black photoresist layer; a barrier layer disposed on the color filter layer; a quantum dot light-emitting layer disposed on the barrier layer, wherein the quantum dot light-emitting layer includes a plurality of quantum dot light-emitting units and a second black photoresist layer, and the plurality of quantum dot light-emitting units are separated by the second black photoresist layer; a scattering layer disposed on side surfaces of the second black photoresist layer adjoining the plurality of quantum dot light-emitting units; and an encapsulation layer disposed on the quantum dot light-emitting layer.

In the quantum dot display device according to an embodiment of the present invention, the side surfaces of the second black photoresist layer adjoining the plurality of quantum dot light-emitting units are inclined surfaces.

In the quantum dot display device according to an embodiment of the present invention, each inclined surface is inclined toward a direction away from one of the plurality of quantum dot light-emitting units adjoining thereto.

In the quantum dot display device according to an embodiment of the present invention, the side surfaces of the second black photoresist layer adjoining the plurality of quantum dot light-emitting units are concave curved surfaces.

In the quantum dot display device according to an embodiment of the present invention, a material of the scattering layer includes a matrix and scattering particles dispersed in the matrix.

In the quantum dot display device according to an embodiment of the present invention, the matrix includes a thermosetting resin, and the scattering particles are selected from titanium dioxide, silicon dioxide, organic silicon compounds, polystyrene, or a combination thereof.

The present invention further provides a method of manufacturing a quantum dot color filter substrate, including: providing a substrate and forming a color filter layer and a first black photoresist layer on the substrate; forming a barrier layer on the color filter layer and the first black photoresist layer; forming a second black photoresist layer on the barrier layer, wherein the second black photoresist layer is defined with a plurality of grooves; applying scattering ink to bottom surfaces of the plurality of grooves; standing the substrate still to allow the scattering ink to gather on side surfaces of the plurality of grooves; curing the scattering ink gathered on the side surfaces of the plurality of grooves with ultraviolet light to form a scattering layer; forming a quantum dot light-emitting layer inside the plurality of grooves; and forming an encapsulation layer on the quantum dot light-emitting layer.

### Beneficial Effect

In the quantum dot color filter substrate and the quantum dot display device proposed by the present invention, scattering ink is printed on the surface of the barrier layer through accurate inkjet printing (IJP) technology. Utilizing the coffee ring effect of the scattering ink on the surface of the barrier layer and the characteristic that the scattering ink has a stronger affinity with the material of the second black photoresist layer to cause the scattering ink gathering at the edge between the barrier layer and the bottom of the second black photoresist layer and climbing along a concave curved surface, thereby forming a scattering film layer on the side surface of the second black photoresist layer. By this method, a scattering layer can be formed on the edge of the second black photoresist layer. When the quantum dot material of the quantum dot color filter layer is excited to emit light, the reflection effect of the scattering layer is utilized to reflect part of the light that should be absorbed by the second black photoresist layer material to achieve the purpose of improving the luminous efficiency of the quantum dot color filter substrate.

### DESCRIPTION OF DRAWINGS

FIG. 1 is a schematic diagram of a cross-sectional structure of a quantum dot color filter substrate according to a first embodiment of the present invention.

FIG. 2 is a schematic diagram of a cross-sectional structure of a quantum dot color filter substrate according to a second embodiment of the present invention.

FIG. 3 is a partially enlarged schematic view of a cross-sectional structure of a second black photoresist layer of the quantum dot color filter substrate in the second embodiment of the present invention before a scattering layer is formed.

FIG. 4 is a schematic diagram of a cross-sectional structure of a quantum dot display device according to a third embodiment of the present invention.

FIG. 5 is an SEM photograph of the second black photoresist layer after the scattering layer is formed in the first embodiment of the present invention.

FIG. 6 is a flow chart of a manufacturing method of the quantum dot color filter substrate according to the present invention.

### DETAILED DESCRIPTION OF PREFERRED EMBODIMENTS

Hereinafter, the quantum dot color filter substrate, the manufacturing method thereof, and the quantum dot display device provided by the embodiments of the present invention will be described in detail with reference to the accompanying drawings. Obviously, the embodiments are only a part of the embodiments of the present invention, rather than all the embodiments. Based on these embodiments of the present invention, all other embodiments obtained by those of ordinary skill in the art without doing creative work shall fall within the protection scope of the present invention.

The description of the embodiments refers to the attached drawings to illustrate specific embodiments in which the present invention can be implemented. The directional terms mentioned in the present invention, such as “above”, “below”, “front”, “back”, “left”, “right”, “inside”, “outside”, “side”, etc., are only directions for referring to the attached drawings. Therefore, the directional terms are used to describe and understand the present invention, rather than limit the present invention. In the drawings, units with similar structures are denoted by the same reference numerals. In the drawings, for clear understanding and ease of description, the thickness of some layers and regions are exaggerated. That is, the size and thickness of each component shown in the drawings are arbitrarily shown, but the present application is not limited thereto.

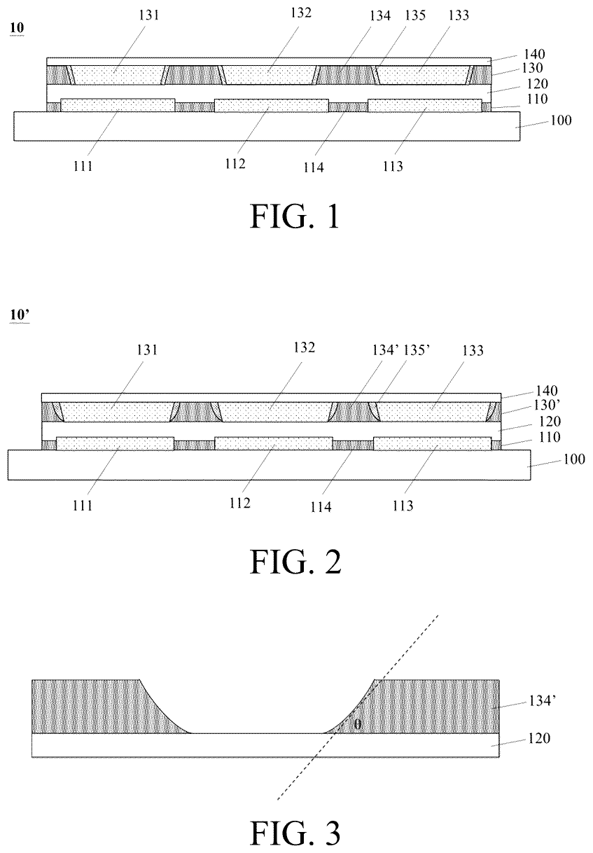

Please refer to FIG. 1. FIG. 1 shows a quantum dot color filter substrate 10 according to a first embodiment of the present invention. The quantum dot color filter substrate 10 includes a substrate 100, a color filter layer 110, a barrier layer 120, a quantum dot light-emitting layer 130, a scattering layer 135, and an encapsulation layer 140. The color filter layer 110 is disposed on the substrate 100, and the color filter layer 110 includes a color photoresist unit 111, a color photoresist unit 112, a color photoresist unit 113, and a first black photoresist layer 114. Specifically, the color photoresist unit 111, the color photoresist unit 112, and the color photoresist unit 113 can be a red photoresist unit, a green photoresist unit, and a blue photoresist unit. The barrier layer 120 is disposed on the color filter layer 110. The barrier layer 120 is preferably composed of materials with better transparency such as silicon dioxide (SiO₂) or silicon nitride (SiNₓ). The quantum dot light-emitting layer 130 is disposed on the barrier layer 120, and the quantum dot light-emitting layer 130 is composed of quantum dot materials. Preferably, the quantum dot material may be, for example, silicon quantum dots, germanium quantum dots, cadmium sulfide quantum dots, or cadmium selenide quantum dots, and the present invention does not impose any limitation on this. The quantum dot light-emitting layer 130 includes a quantum dot light-emitting unit 131, a quantum dot light-emitting unit 132, a light-transmitting layer 133, and a second black photoresist layer 134. Specifically, the quantum dot light-emitting unit 131 and the quantum dot light-emitting unit 132 can be a red quantum dot light-emitting unit and a green quantum dot light-emitting unit. The plurality of quantum dot light-emitting units are separated by the second black photoresist layer 134 to prevent crosstalk of light emitted by the quantum dot light-emitting units of different colors after being excited. In a specific embodiment, the quantum dot light-emitting unit 131, the quantum dot light-emitting unit 132, and the light-transmitting layer 133 are all in the shape of a trapezoidal cone. The scattering layer 135 is disposed on the side surface of the second black photoresist layer 134 adjoining the plurality of quantum dot light-emitting units (131, 132) and the light-transmitting layer 133. The encapsulation layer 140 is disposed on the quantum dot light-emitting layer 130 to ensure that the quantum dot light-emitting layer 130 will not be damaged by the intrusion of moisture or other substances. Specifically, the projections of the plurality of quantum dot light-emitting units (131, 132) and the light-transmitting layer 133 on the substrate 100 correspond to the projections of the plurality of color photoresist units (111, 112, 113) on the substrate 100 in a one-to-one correspondence. The area of the light-emitting surface of each of the plurality of quantum dot light-emitting units (131,132) and the light-transmitting layer 133 is less than or equal to the area of the light-receiving surface of each of the plurality of color photoresist units (111,112,113) to ensure that the colored light emitted by each of the plurality of quantum dot light-emitting units after being excited can pass through the color photoresist unit.

In a preferred embodiment, a side surface of the second black photoresist layer 134 adjoining any of the plurality of quantum dot light-emitting units (131, 132) and the light-transmitting layer 133 is an inclined surface.

In a preferred embodiment, each inclined surface is inclined in a direction away from one of the plurality of quantum dot light-emitting units (131, 132) or the light-transmitting layer 133 adjoining thereto.

In a preferred embodiment, the material of the scattering layer 135 mainly includes a matrix and scattering particles dispersed in the matrix.

In a preferred embodiment, the matrix may include a thermosetting resin, such as acrylic resin. The scattering particles can be selected from materials with scattering properties, such as titanium dioxide, silicon dioxide, organic silicon compounds, polystyrene, or a combination thereof.

In the foregoing embodiment, the specific method for forming the scattering layer 135 is: Before forming the quantum dot light-emitting layer 130, scattering ink droplets are printed on the surface of the barrier layer 120 in the groove of the second black photoresist layer 134 in advance. Specifically, the formulation of the scattering ink includes scattering particles, acrylic resin, photoinitiator, solvent, and the like. As mentioned above, the scattering particles are selected from the particles with scattering properties such as titanium dioxide, silicon dioxide, organic silicon compounds, polystyrene, or a combination thereof. Specifically, the scattering particles can be selected from titanium dioxide and silicon dioxide. The mixing ratio can be as follows: titanium dioxide accounts for 88-92% by weight, and silicon dioxide accounts for 8-12% by weight. Because titanium dioxide has good scattering properties, it can play a very good scattering effect as scattering particles. Meanwhile, besides its good scattering properties, silicon dioxide also has the effect of anti-caking. Therefore, the silicon dioxide can be used as an anti-caking agent in the scattering ink including the titanium dioxide to prevent the titanium dioxide from agglomerating in the scattering ink solvent and affecting its scattering performance. The solvent is higher alkanes (more than 10 carbon atoms). The solvent accounts for 10% by weight or more of the scattering ink. In addition, the scattering ink further includes a photoinitiator, which is used to subsequently cure the scattering ink by irradiating ultraviolet light to form the scattering layer 135.

As stated above, when the scattering ink droplets are printed on the surface of the barrier layer 120 in the groove of the second black photoresist layer 134, under the action of the coffee ring effect, the scattering ink droplets will form a liquid flow flowing from the center to the edge on a surface of the barrier layer 120 in the groove. This liquid flow can bring almost all the solute particles (scattering particles) in the scattering ink droplets to the edge of the second black photoresist layer 134 there. In this situation, the second black photoresist layer 134 on the surface of the barrier layer 120 has an inclined surface with the same inclined direction as the flow direction of the liquid flow, which helps the scattering ink to climb more easily and adhere to the side of the second black photoresist layer 134.

Please refer to FIG. 2, which shows a quantum dot color filter substrate 10′ according to a second embodiment of the present invention. Similar to the aforementioned first embodiment, the quantum dot color filter substrate 10′ includes a substrate 100, a color filter layer 110, a barrier layer 120, a quantum dot light-emitting layer 130′, a scattering layer 135′, and an encapsulation layer 140. The color filter layer 110 is disposed on the substrate 100, and the color filter layer 110 includes a color photoresist unit 111, a color photoresist unit 112, a color photoresist unit 113, and a first black photoresist layer 114. Specifically, the color photoresist unit 111, the color photoresist unit 112′, and the color photoresist unit 113 can be a red photoresist unit, a green photoresist unit, and a blue photoresist unit. The barrier layer 120 is disposed on the color filter layer 110. The barrier layer 120 is preferably composed of materials with better transparency such as silicon dioxide (SiO₂) or silicon nitride (SiNₓ). The quantum dot light-emitting layer 130′ is disposed on the barrier layer 120, and the quantum dot light-emitting layer 130′ is composed of quantum dot materials. Preferably, the quantum dot material may be, for example, silicon quantum dots, germanium quantum dots, cadmium sulfide quantum dots, or cadmium selenide quantum dots, and the present invention does not impose any limitation on this. The quantum dot light-emitting layer 130′ includes a quantum dot light-emitting unit 131, a quantum dot light-emitting unit 132, a light-transmitting layer 133, and a second black photoresist layer 134′. Specifically, the quantum dot light-emitting unit 131 and the quantum dot light-emitting unit 132 can be a red quantum dot light-emitting unit and a green quantum dot light-emitting unit. The plurality of quantum dot light-emitting units and the light-transmitting layer 133 are separated by the second black photoresist layer 134 to prevent crosstalk of light emitted by the quantum dot light-emitting units of different colors after being excited. In a specific embodiment, the quantum dot light-emitting unit 131, the quantum dot light-emitting unit 132, and the light-transmitting layer 133 are all in the shape of a trapezoidal cone.

In a preferred embodiment, the side surface of the second black photoresist layer 134′ adjoining the quantum dot light-emitting unit (131, 132) and the light-transmitting layer 133 is a concave curved surface. Please refer to FIG. 3 together. FIG. 3 shows a partially enlarged schematic view of a cross-sectional structure of a second black photoresist layer 134′ of the quantum dot color filter substrate 10′ in the second embodiment of the present invention before a scattering layer 135′ is formed. It can be clearly seen from FIG. 3 that the side surface of the second black photoresist layer 134′ is a concave curved surface. Specifically, the angle θ between the tangent line at the midpoint of the concave curved surface of the second black photoresist layer 134′ and the horizontal plane of the barrier layer 120 ranges from 45 to 60 degrees. The slope ratio of the concave curved surface, that is, the ratio of the vertical height to the horizontal width of the slope is between 1:1 and 1.73:1. Compared with the side surface of the second black photoresist layer 134 in the first embodiment which is a straight and inclined surface, the side surface of the second black photoresist layer 134′ in this embodiment is a concave curved surface, which is more conducive to the formation of the scattering layer 135′.

In this embodiment, the side surface of the second black photoresist layer 134′ under this design has a relatively gentle slope. When the scattering ink droplets are printed on the surface of the barrier layer 120 in the groove of the second black photoresist layer 134′, under the action of the coffee ring effect, the scattering ink droplets will form a liquid flow flowing from the center to the edge on the surface in the groove of the second black photoresist layer 134′. This liquid flow can bring almost all the solute particles (scattering particles) in the scattering ink droplets to the edge of the second black photoresist layer 134′ there. In this situation, because the side surface of the second black photoresist layer 134′ on the barrier layer 120 is a concave curved surface with a relatively gentle slope, it is more conducive for the solute particles of the scattering ink droplets to climb and adhere to the side surface of the second black photoresist layer 134′.

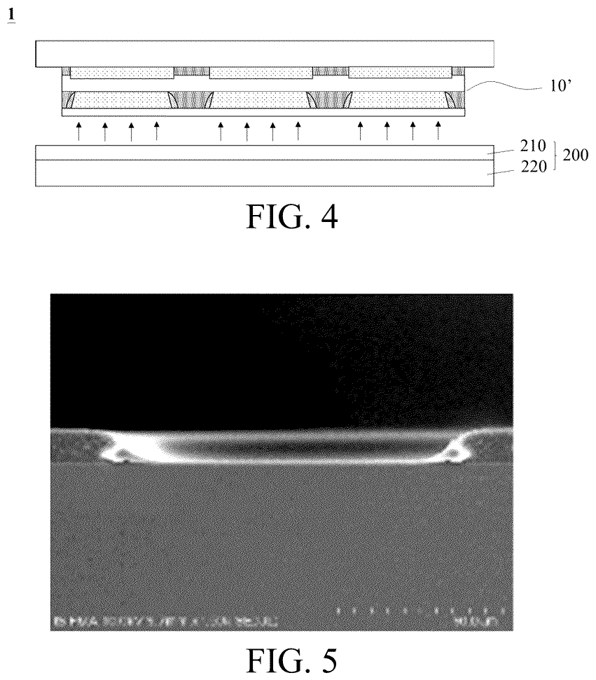

Please refer to FIG. 4, which shows a quantum dot display device 1 according to a third embodiment of the present invention. The quantum dot display device 1 includes a quantum dot color filter substrate 10′ and a backlight substrate 200. Please refer to FIG. 2 and FIG. 4 together. The quantum dot color filter substrate 10′ includes a substrate 100, a color filter layer 110, a barrier layer 120, a quantum dot light-emitting layer 130′, a scattering layer 135′, and an encapsulation layer 140. The backlight substrate 200 is provided opposite to the quantum dot color filter substrate 10′. Specifically, the backlight substrate 200 includes a glass substrate 220 and an organic light-emitting diode device layer 210. In this embodiment, the organic light-emitting diode device layer 210 includes a blue organic light-emitting diode device. Specifically, the organic light-emitting diode device layer 210 includes an anode layer, a hole injection layer, a hole transport layer, an organic electroluminescence layer, an electron transport layer, and a cathode layer (not shown individual film layers in the figure).

Please refer to FIG. 2 and FIG. 4 together. In a preferred embodiment, the side surfaces of the second black photoresist layer 134′ adjoining the plurality of quantum dot light-emitting units (131, 132) and the light-transmitting layer 133 are concave curved surfaces.

In a preferred embodiment, the material of the scattering layer 135′ includes a matrix and scattering particles dispersed in the matrix.

In a preferred embodiment, the matrix may include a thermosetting resin, such as acrylic resin. The scattering particles can be selected from materials with scattering properties, such as titanium dioxide, silicon dioxide, organic silicon compounds, polystyrene, or a combination thereof.

In this embodiment, the backlight substrate 200 provides a blue light source to the quantum dot color filter substrate 10′. The blue light source excites the quantum dot light-emitting units (131, 132) to emit red light and green light, respectively, and the light-transmitting layer 133 is used to transmit blue light. A scattering layer 135′ is formed on the side of the second black photoresist layer 134′. The reflection effect of the scattering layer 135′ is used to reflect part of the light that should be absorbed by the material of the second black photoresist layer 134′ to achieve the purpose of improving the luminous efficiency of the quantum dot display device 1.

Please refer to FIG. 5. FIG. 5 is a photograph of a cross-section of a quantum dot color filter substrate taken by a scanning electron microscope (SEM). The SEM photo shows that the aforementioned coffee ring effect is used to print the scattering ink to form a scattering layer on the side of the second black photoresist layer. The present invention utilizes the scattering layer to reflect the light emitted after the quantum dot material is excited, which can effectively reduce the excitation light absorbed by the second black photoresist layer material, thereby improving the light extraction efficiency of the quantum dot color filter substrate.

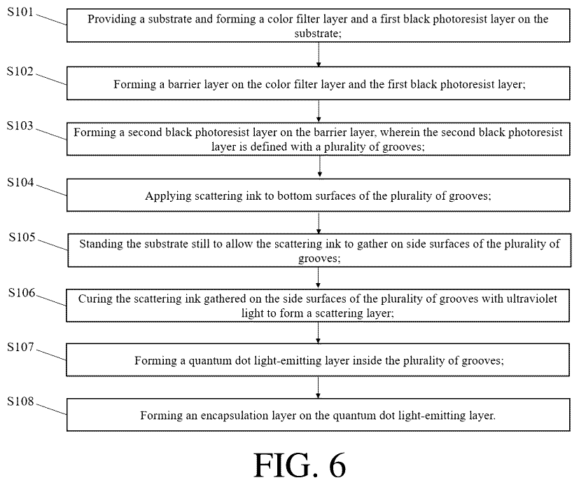

Please refer to FIG. 6. FIG. 6 shows a flow chart of a manufacturing method of the quantum dot color filter substrate according to the present invention, including:
S101, providing a substrate and forming a color filter layer and a first black photoresist layer on the substrate;
S102, forming a barrier layer on the color filter layer and the first black photoresist layer;
S103, forming a second black photoresist layer on the barrier layer, wherein the second black photoresist layer is defined with a plurality of grooves;
S104, applying scattering ink to bottom surfaces of the plurality of grooves;
S105, standing the substrate still to allow the scattering ink to gather on side surfaces of the plurality of grooves;
S106, curing the scattering ink gathered on the side surfaces of the plurality of grooves with ultraviolet light to form a scattering layer;
S107, forming a quantum dot light-emitting layer inside the plurality of grooves; and
S108, forming an encapsulation layer on the quantum dot light-emitting layer.

Specifically, the substrate can be a glass substrate, and the color filter layer and the first black photoresist layer are formed in a conventional process. The barrier layer can be formed by physical or chemical vapor deposition. The second black photoresist layer can be formed by photoresist coating, exposure, and development. The second black photoresist layer is defined with a plurality of grooves, and the side surface of the plurality of grooves is preferably a concave curved surface. The formulation of the scattering ink includes scattering particles, acrylic resin, photoinitiator, solvent, and the like. As mentioned above, the scattering particles are selected from the particles with scattering properties such as titanium dioxide, silicon dioxide, organic silicon compounds, polystyrene, or a combination thereof. Specifically, the scattering particles can be selected from titanium dioxide and silicon dioxide. The mixing ratio can be as follows: titanium dioxide accounts for 88-92% by weight, and silicon dioxide accounts for 8-12% by weight. Because titanium dioxide has good scattering properties, it can play a very good scattering effect as scattering particles. Meanwhile, besides its good scattering properties, silicon dioxide also has the effect of anti-caking. Therefore, the silicon dioxide can be used as an anti-caking agent in the scattering ink including the titanium dioxide to prevent the titanium dioxide from agglomerating in the scattering ink solvent and affecting its scattering performance. The solvent is higher alkanes (more than 10 carbon atoms). The solvent accounts for 10% by weight or more of the scattering ink.

As mentioned above, as shown in FIG. 1 and FIG. 2 of the present invention, the first embodiment of the present invention designs the side surface of the second black photoresist layer 134 as an inclined surface. The inclined surface is inclined in the direction away from the quantum dot light-emitting unit (131, 132) (or the light-transmitting layer 133) adjoining thereto. That is, the cross-sections of the quantum dot light-emitting unit 132 and the light-transmitting layer 133 are in an inverted trapezoid shape.

Furthermore, in the second embodiment of the present invention, the side surface of the second black photoresist layer 134′ is designed as a concave curved surface. Both of these designs are beneficial to the formation of the scattering layer 135 (135′). Wherein, compared to the side surface of the second black photoresist layer 134 in the first embodiment being an inclined surface, the side surface of the second black photoresist layer 134′ in the second embodiment is a concave curved surface, which is more conducive to the formation of the scattering layer 135′. The side surface of the second black photoresist layer 134′ under this design has a relatively gentle slope. When the scattering ink droplets are printed on the surface of the barrier layer 120 in the groove of the second black photoresist layer 134′, under the action of the coffee ring effect, the scattering ink droplets will form a liquid flow flowing from the center to the edge on the surface of the barrier layer 120 in the groove. This liquid flow can bring almost all the solute particles in the scattering ink droplets to the edge of the second black photoresist layer there. In this situation, because the side surface of the second black photoresist layer 134′ on the barrier layer 120 is a concave curved surface with a relatively gentle slope, it is more conducive for the solute particles of the scattering ink droplets to climb and adhere to the side surface of the second black photoresist layer 134′ to form the scattering layer 135′.

The present invention utilizes the coffee ring effect to form a scattering layer on the side surface of the second black photoresist layer adjoining the plurality of quantum dot light-emitting units. When the quantum dot material of the quantum dot color filter layer is excited to emit light, part of the light that should be absorbed by the second black photoresist layer material is reflected by the reflection effect of the scattering layer, thereby achieving the purpose of improving the luminous efficiency of the quantum dot color filter substrate.

The above description is only the preferred embodiments of the present invention. It should be noted that for those of ordinary skill in the art, without departing from the principle of the present invention, several improvements and modifications can be made. These improvements and modifications should also be regarded as the protection scope of the present invention.

1. A quantum dot color film substrate, comprising:
a substrate;
a color filter layer disposed on the substrate, wherein the color filter layer comprises a plurality of color photoresist units and a first black photoresist layer;
a barrier layer disposed on the color filter layer;
a quantum dot light-emitting layer disposed on the barrier layer, wherein the quantum dot light-emitting layer comprises a plurality of quantum dot light-emitting units and a second black photoresist layer, and the plurality of quantum dot light-emitting units are separated by the second black photoresist layer;
a scattering layer disposed on side surfaces of the second black photoresist layer adjoining the plurality of quantum dot light-emitting units; and
an encapsulation layer disposed on the quantum dot light-emitting layer.

2. The quantum dot color film substrate of claim 1, wherein the side surfaces of the second black photoresist layer adjoining the plurality of quantum dot light-emitting units are inclined surfaces.

3. The quantum dot color film substrate of claim 2, wherein each inclined surface is inclined in a direction away from one of the plurality of quantum dot light-emitting units adjoining thereto.

4. The quantum dot color film substrate of claim 1, wherein the side surfaces of the second black photoresist layer adjoining the plurality of quantum dot light-emitting units are concave curved surfaces.

5. The quantum dot color film substrate of claim 1, wherein a material of the scattering layer comprises a matrix and scattering particles dispersed in the matrix.

6. The quantum dot color film substrate of claim 5, wherein the matrix comprises a thermosetting resin selected from titanium dioxide, silicon dioxide, organic silicon compounds, polystyrene, or a combination thereof.

7. A quantum dot display device, comprising:
a quantum dot color film substrate; and
a backlight substrate arranged opposite to the quantum dot color film substrate;
wherein the backlight substrate is selected from any of a blue organic light-emitting diode substrate, a blue micro light-emitting diode substrate, or a blue submillimeter light-emitting diode substrate; and the quantum dot color film substrate comprises:
a substrate;
a color filter layer disposed on the substrate, wherein the color filter layer comprises a plurality of color photoresist units and a first black photoresist layer;
a barrier layer disposed on the color filter layer;
a quantum dot light-emitting layer disposed on the barrier layer, wherein the quantum dot light-emitting layer comprises a plurality of quantum dot light-emitting units and a second black photoresist layer, and the plurality of quantum dot light-emitting units are separated by the second black photoresist layer;
a scattering layer disposed on side surfaces of the second black photoresist layer adjoining the plurality of quantum dot light-emitting units; and
an encapsulation layer disposed on the quantum dot light-emitting layer.

8. The quantum dot display device of claim 7, wherein the side surfaces of the second black photoresist layer adjoining the plurality of quantum dot light-emitting units are inclined surfaces.

9. The quantum dot display device of claim 8, wherein each inclined surface is inclined in a direction away from one of the plurality of quantum dot light-emitting units adjacent thereto.

10. The quantum dot display device of claim 7, wherein the side surfaces of the second black photoresist layer adjoining the plurality of quantum dot light-emitting units are concave curved surfaces.

11. The quantum dot display device of claim 7, wherein a material of the scattering layer comprises a matrix and scattering particles dispersed in the matrix.

12. The quantum dot display device of claim 11, wherein the matrix comprises a thermosetting resin, and the scattering particles are selected from titanium dioxide, silicon dioxide, organic silicon compounds, polystyrene, or a combination thereof.

13. A manufacturing method of a quantum dot color film substrate, comprising:
providing a substrate and forming a color filter layer and a first black photoresist layer on the substrate;
forming a barrier layer on the color filter layer and the first black photoresist layer;
forming a second black photoresist layer on the barrier layer, wherein the second black photoresist layer is defined with a plurality of grooves;
applying scattering ink to bottom surfaces of the plurality of grooves;
standing the substrate still to allow the scattering ink to gather on side surfaces of the plurality of grooves;
curing the scattering ink gathered on the side surfaces of the plurality of grooves with ultraviolet light to form a scattering layer;
forming a quantum dot light-emitting layer inside the plurality of grooves; and
forming an encapsulation layer on the quantum dot light-emitting layer.
